(19) United States
(12) Patent Application Publication
(10) Pub. No.: US 2015/0159268 A1
(43) Pub. Date: Jun. 11, 2015

(54) METHOD OF DEPOSITION OF HIGHLY SCRATCH-RESISTANT DIAMOND FILMS ONTO GLASS SUBSTRATES BY USE OF A PLASMA-ENHANCED CHEMICAL VAPOR DEPOSITION

(71) Applicant: Rubicon Technology, Inc., Bensenville, IL (US)

(72) Inventor: John P. CIRALDO, Elgin, IL (US)

(21) Appl. No.: 14/529,981

(22) Filed: Oct. 31, 2014

Related U.S. Application Data
(60) Provisional application No. 61/914,582, filed on Dec. 11, 2013.

(51) Int. Cl. C23C 16/27; C23C 16/458; C23C 16/52; C23C 16/511

(52) U.S. Cl. CPC C23C 16/274; C23C 16/511; C23C 16/4586; C23C 16/52

(57) ABSTRACT

A system and process for inter alia coating or creating a substrate with a layer of carbon or diamond film using a microwave field and a hydrocarbon gas environment. The carbon or diamond film creates a stronger and more scratch resistant substrate that is less prone to breaking or cracking. Additionally, the coating may provide superior heat transfer properties enabling the final device to be used in passive cooling applications such as for mobile phone displays.

### CROSS-REFERENCE TO RELATED APPLICATIONS

This application claims benefit and priority to U.S. Provisional Application No. 61/914,582, filed Dec. 11, 2013, the disclosure of which is incorporated by reference herein in its entirety.

### BACKGROUND OF THE DISCLOSURE

1.0 Field of the Disclosure

The present disclosure relates to a system, a method, and a device for inter alia coating a transparent material (such as, e.g., a substrate) in a gas environment using microwave sources in order to create a cost-effective hard, scratch-resistant coating demonstrating superior thermal properties.

2.0 Related Art

Hard, scratch resistant windows are necessary for cell phones and other devices that are subject to harsh conditions during use. While full diamond windows are an ideal solution for this problem, their use has been cost-prohibitive. Therefore, a technique to provide a diamond type glass window of similar hardness and scratch resistance at a lower cost would be very useful in many applications such as, e.g., consumer electronics, including in some instances, such as, e.g., a touch screen for a mobile device, it may be desirable for the window to demonstrate a high level of heat conductance, thereby allowing for the passive cooling of the device.

Y. Mokuno et al, in their article in “Diamond and Related Materials 14” (2005) 1743-1746, describes synthesizing single-crystal diamonds by repetition of high rate homoepitaxial growth by microwave plasma CVD.

S. T. Lee, et al., in their article in “Materials Science and Engineering 25” (1999) 123-154, discusses the various low-pressure growth methods of diamond films.

### SUMMARY OF THE DISCLOSURE

According to one non-limiting example of the disclosure, a system, a method, and a device are provided to inter alia coating a material (such as, e.g., a substrate) through gas flow and microwave sources in order to create a cost-effective, hard, scratch-resistant diamond-based coating. This coating may also possess superior thermal properties such that it can be used to passively cool electronic devices.

In one aspect, a substrate is exposed to microwave radiation in a chamber of hydrogen and one or more hydrocarbon gases to form a carbon film on the substrate. The chamber may be evacuated to a partial pressure. Then carbon may be a diamond allotrope.

In one aspect, a substrate may be created having an applied carbon film. The substrate may be transparent. The applied carbon film may be a diamond film. The applied carbon film may comprise a diamond film that creates a matrix with the transparent substrate and may be formed with or at the surface of the substrate. The matrix, comprising the transparent substrate and the carbon film on one or more surfaces of the substrate, may be substantially transparent. The substrate may comprise one of: glass, borosilicate glass, ion-exchange glass, aluminosilicate glass, yttria-stabilized zirconia, quartz, transparent aluminum-oxide, and a transparent plastic.

In one aspect, a system for forming a film on a substrate is provided including a source of gas that provides at least a carbon-based gas, a holding device to hold a target substrate, an environment configured to contain the gas about the target substrate, and a microwave source configured to project a microwave field towards the target substrate to create a carbon film upon the target substrate for creating a stronger and more scratch-resistant substrate. The gas may be or include a hydrogen-based gas. The gas may be or include a hydrocarbon gas. The gas may be methane. The gas may include an inert gas. The gas may include at least one of oxygen and nitrogen. The carbon film may be diamond film. The target substrate may comprise one of: glass, borosilicate glass, aluminosilcate glass, yttria-stabiltzed zirconia, quartz, transparent aluminum-oxide, and a transparent plastic. The target substrate may comprise ion-exchange glass. The environment may comprise a chamber configured to create a partial pressure of gas and the microwave source is configured to excite the gas to create plasma within the chamber to deposit the carbon film on the target substrate. The thickness of the created carbon film may be about 1 nm to about 10 μm; but may be more or less. The target substrate with carbon film may comprise a window usable in at least one of: a mobile phone, a tablet computer, a watch crystal, a laptop computer, and a consumer device. The system may further comprise a computer controller that is configured to control at least one of: targeting of the microwave source, positioning of the holding device relative to the microwave source, flow of the gas, temperature of the holding device, start and stop times of the microwave field, intensity of the microwave field, orientation of the substrate, pressure of the environment, and a thickness of the carbon film.

In one aspect, a process to create a carbon film on a substrate is provided that includes the steps of providing a gas that includes a hydrocarbon gas, and directing a microwave field towards a substrate, wherein the substrate is in contact with the hydrocarbon gas, the microwave field creating plasma to produce a layer of carbon film on the substrate thereby producing a stronger and more scratch resistant substrate. The film may be a diamond film. The providing step may provide an environment of the gas, wherein the substrate is in the gas environment. The process may further include the step of providing a holding device to hold the substrate, wherein the holding device is temperature controlled and adjustable in orientation. The substrate may comprise one of: glass, borosilicate glass, aluminosilcate glass, yttria-stabiltzed zirconia, quartz, transparent aluminum-oxide and a transparent plastic. The substrate may comprise ion-exchange glass. The process may further comprise providing a computer controller that is configured to control at least one of: targeting of the microwave source, positioning of the holding device relative to the microwave source, flow of the gas, temperature of the holding device, start and stop times of the microwave filed, intensity of the microwave field, orientation of the substrate, pressure of the environment, and a thickness of the carbon film. The directing step may create a carbon film having a thickness of about 1 nm to about 10 μm. the directing step may create a window usable in at least one of: a mobile phone, a tablet computer, a watch crystal, a laptop computer, and a consumer device.

Additional features, advantages, and embodiments of the disclosure may be set forth or apparent from consideration of the detailed description, drawings and attachment. Moreover, it is to be understood that the foregoing summary of the disclosure and the following detailed description, drawings and attachment are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate embodiments of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 shows an example of a device for coating a material (such as, e.g., a substrate) utilizing a gas environment and a microwave source, according to the principles of the disclosure;

FIG. 2 shows an example of a device for coating a material (such as, e.g., a substrate) utilizing a gas environment and a microwave source, according to the principles of the disclosure; and

FIG. 3 is a flow diagram of an example process, the steps of the process performed according to the principles of the disclosure.

The present disclosure is further described in the detailed description that follows.

### DETAILED DESCRIPTION OF THE DISCLOSURE

The disclosure and the various features and advantageous details thereof are explained more fully with reference to the non-limiting embodiments and examples that are described and/or illustrated in the accompanying drawings and detailed in the following description. It should be noted that the features illustrated in the drawing are not necessarily drawn to scale, and features of one embodiment may be employed with other embodiments as the skilled artisan would recognize, even if not explicitly stated herein. Descriptions of well-known components and processing techniques may be omitted so as to not unnecessarily obscure the embodiments of the disclosure. The examples used herein are intended merely to facilitate an understanding of ways in which the disclosure may be practiced and to further enable those of skill in the art to practice the embodiments of the disclosure. Accordingly, the examples and embodiments herein should not be construed as limiting the scope of the disclosure. Moreover, it is noted that like reference numerals represent similar parts throughout the several views of the drawings.

The terms “including”, “comprising” and variations thereof, as used in this disclosure, mean “including, but not limited to”, unless expressly specified otherwise.

The terms “a”, “an”, and “the”, as used in this disclosure, means “one or more”, unless expressly specified otherwise. The term “about” means within +/−10% unless context indicates otherwise.

Devices that are in communication with each other need not be in continuous communication with each other, unless expressly specified otherwise. In addition, devices that are in communication with each other may communicate directly or indirectly through one or more intermediaries.

Although process steps, method steps, algorithms, or the like, may be described in a sequential order, such processes, methods and algorithms may be configured to work in alternate orders. In other words, any sequence or order of steps that may be described does not necessarily indicate a requirement that the steps be performed in that order. The steps of the processes, methods or algorithms described herein may be performed in any order practical. Further, some steps may be performed simultaneously.

When a single device or article is described herein, it will be readily apparent that more than one device or article may be used in place of a single device or article. Similarly, where more than one device or article is described herein, it will be readily apparent that a single device or article may be used in place of the more than one device or article. The functionality or the features of a device may be alternatively embodied by one or more other devices which are not explicitly described as having such functionality or features.

Currently, the inventors are not aware of any known product or patent related to diamond windows or diamond films for mobile electronic devices (or other devices) for protection thereof “Gorilla® Glass,” a type of ion-exchange glass, produced by Corning® is a hardened glass that is used in many mobile devices to reduce surface scratches and the likelihood of cracking the screen. However, the properties of Gorilla® Glass are inferior to diamond. Moreover, sapphire products are also an inferior product to diamond.

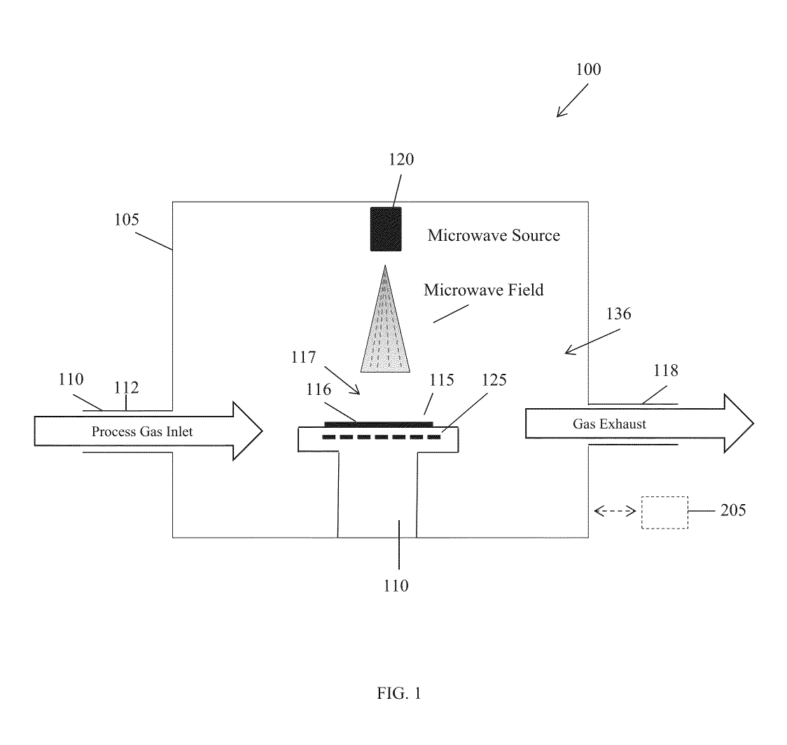

FIG. 1 shows an example of a device for coating a material, such as, e.g., a substrate, with a deposited carbon film, according to the principles of the disclosure. As seen, the device 100 may include an evacuation chamber 105 configured to create a partial pressure of process gas 110, including molecular or atomic hydrogen, as well as one or more hydrocarbons, which may include, but are not limited to, methane. Additionally, the environmental gas process may also contain nitrogen, oxygen, inert gases such as argon, and other process gasses. The stage 125 for supporting or holding the target material 115 may itself be temperature controlled, i.e., cooled or heated. The gas 110 may flow from a source 112 and exit out an exhaust 118.

The device in FIG. 1 may be used to coat a layer of carbon film 116 on a material (e.g., substrate) to provide a transparent, scratch-resistant surface. In some applications, the resulting product may not be transparent, rather, translucent or even opaque. The resultant window may have applications for many consumer products including, e.g., touch screens in a mobile phone, tablet computer, a watch crystal and a laptop computer, where maintaining a scratch-free surface is of primary importance. Moreover, the resulting product may be used in industrial type applications where optically transparent scratch resistant windows may be required. The coating may provide additional thermal benefit in applications such as consumer electronic devices and optics for high-power lasers, where heat management issues create a need for passive cooling via the optical interface.

A benefit provided by this invention includes, but is not limited to, superior mechanical performance, such as, e.g., improved scratch resistance, improved thermal properties due to the high heat conductivity of diamond based films, greater resistance to cracking compared to currently used materials such as glass, plastic, etc. Additionally, by using diamond film coated on glass rather than, e.g., an entire diamond window, the cost may be reduced substantially, making the product available for widespread consumer usage.

According to an aspect of the disclosure, an arbitrary substrate, such as, e.g., glass, quartz, or the like, may be placed onto a stage 125 (which may be a type of holding device) within an evacuated chamber 105. The stage 125 may or may not be cooled. The substrate or target material 115 (such as, e.g., glass, borosilicate glass, ion-exchange glass, aluminosilicate glass, yttria-stabilized zirconia (YSZ), transparent plastics, and the like) may be placed on the stage 125. The stage 125 may be configured or adjustable to move in any one or more dimensions of 3-D space. Upon achieving an appropriate partial pressure 136, the gas may be excited by a microwave source 120 in order to introduce plasma 117 within device 100 (or 200). The gas composition being such that carbon film 116 may be deposited onto the target material 115. While various allotropes of carbon may be deposited, the gas composition can be maintained in such a fashion as to preferentially etch non-diamond allotropes, leaving a final deposition that is primarily of the diamond allotrope of carbon. The thickness of the film 116 created on the substrate 115 being arbitrary and may be related to the specific application, and customizable from a few nanometers to many microns, such as may be needed by a particular application. For example, the thickness may be created that is a thickness that selected from a range of about 1 nm to about 10 μm. However, greater (or even less) thicknesses may be achieved, as needed. The thickness can be any thickness selected from the range of about 2 nm to about 100 nm. Moreover, the thickness can be any thickness selected from the range of about 100 nm to about 5 mm. Moreover, the thickness can be greater than 10 μm.

The orientation, relative position, power, and frequencies may vary of the microwave source 120. Moreover, one or more surfaces of the target material 115 may be targeted for carbon film deposition.

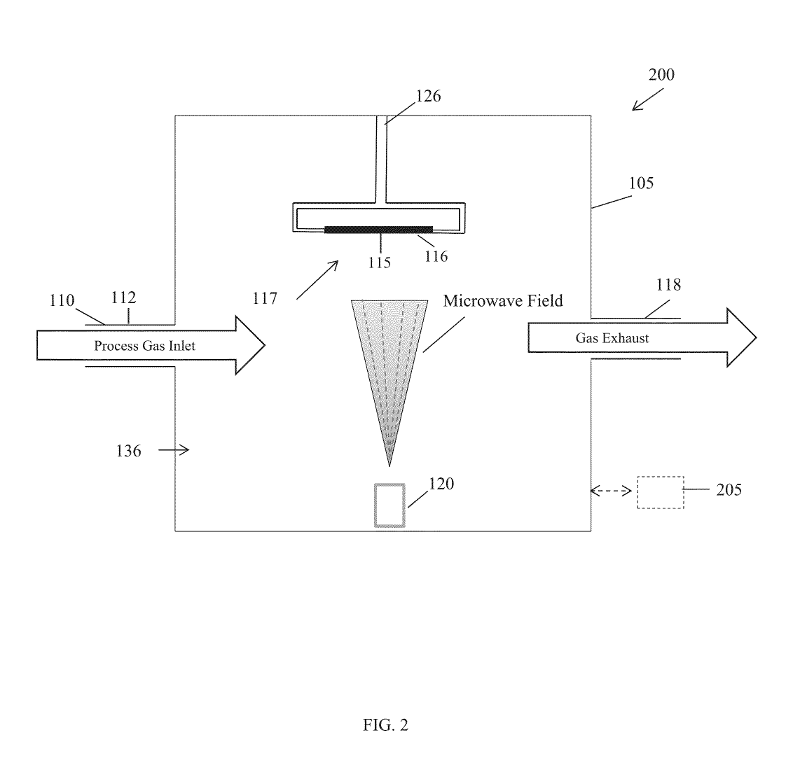

FIG. 2 shows an example of a device for coating a material, such as, e.g., a substrate, with a deposited carbon film, according to the principles of the disclosure. The example of FIG. 2 is similar to the example of FIG. 1, but shows a different orientation of the microwave source 120 relative to the substrate 115. In this example, the microwave source 120 is oriented or located below the substrate 115. In other implementations, the relative orientation of the microwave source 120 and the substrate 115 may be any practical configuration. The microwave source 120 and the substrate 115 may be proximate one another.

The substrate 115 (or holding device) may comprise multiple surfaces to have a carbon film/diamond created thereupon. A securing device 126 may be used to hold the substrate 115 in different positions relative to the microwave source 120. The securing device 115 may be adjustable in two or more different axis. The securing device 126 may be cooled or heated, as warranted, to improve deposition of the carbon film thereon. Moreover, a computer controller 205 may control the operations of the various components of the systems 100 and 200. For example, the controller 205 may control at least one of: the gas flow, the temperatures of the stage 125 and the securing device 126, the start and stop times of the microwave field, the intensity of the microwave field, targeting of the microwave field towards the substrate which may be selective targeting on a portion of the substrate, orientation of the substrate 115, the pressure(s) within the chamber 105, including possible evacuation of the chamber 105, thickness of the carbon film on the substrate, process duration, and the like.

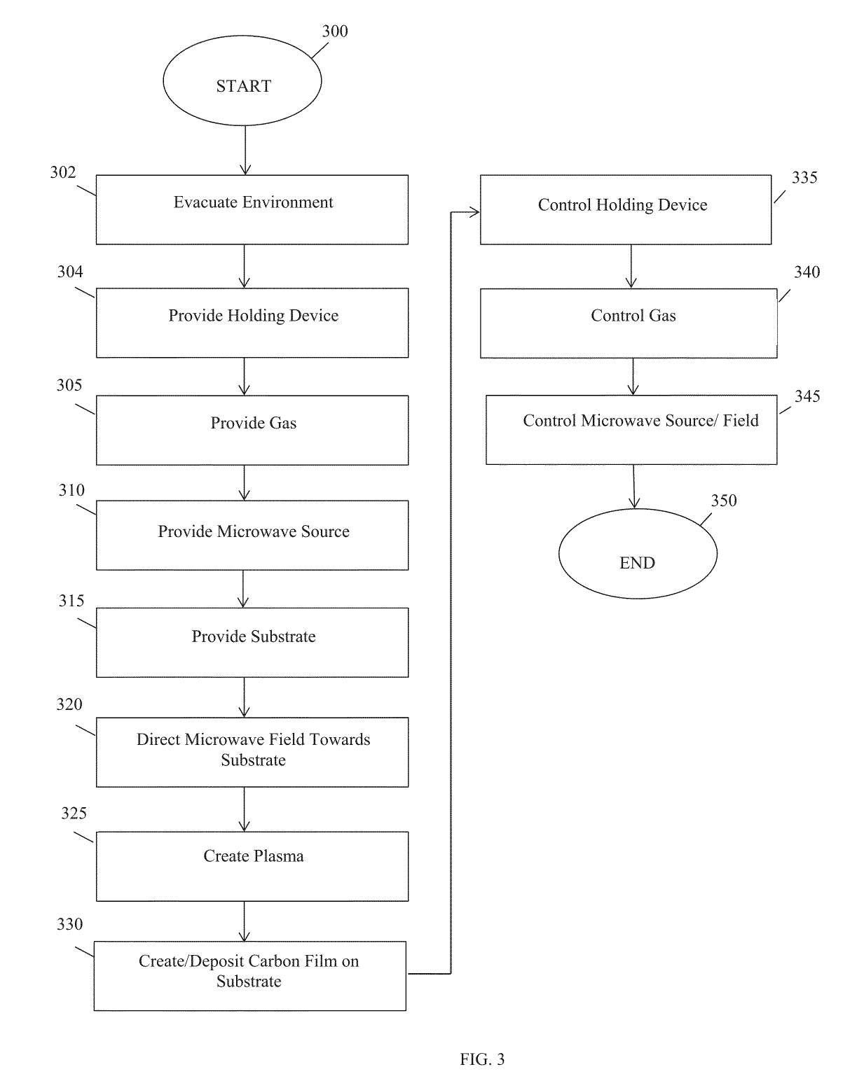

FIG. 3 is a flow diagram of an example process, the steps of the process performed according to principles of the disclosure, starting at step 300. The steps of this process may be in alternate order than as shown. At step 302, an environment such as, e.g., chamber 105 may be evacuated. At step 304, a holding device such as, e.g., may be provided. At step 305, process gas may be provided. This may be provided in an environment such as, e.g., that shown in FIG. 1 or FIG. 2. The process gas may include one or more of a carbon-based gas, a hydrocarbon-based gas, methane, an inert gas, oxygen and nitrogen. This step may include creating a partial pressure of the process gas in an environment such as chamber 105. The environment may be evacuated prior to providing the process gas. The process gas may be flowed as necessary into the environment such as chamber 105 to provide a continual source of carbon for as long as required by a particular iteration of the process.

At step 310, a microwave source is provided. This may include providing a microwave generator within or proximate a gas chamber such as chamber 105. At step 315, a substrate may be provided. The substrate may be held by the holding device such as, e.g., securing device 115 or stage 125. The substrate may comprise, e.g., one of: glass, borosilicate glass, ion-exchange glass, aluminosilicate glass, yttria-stabilized zirconia, quartz, transparent aluminum-oxide and a transparent plastic.

At step 320, the microwave source, such as, e.g., microwave source 120, may provide a microwave field directed towards the substrate and/or process gas. At step 325, plasma may be created by the microwave field. At step 330, a carbon film may be deposited on the substrate. The deposited carbon film may comprise a diamond film.

At step 335, the holding device may be controlled such as by controller 205. The holding device such as, e.g., securing device 115 or stage 125 may be repositioned to reorient the substrate in relation to the microwave source. This may reorient the substrate in one or more of three dimensions. The holding device may also be controlled to raise or lower its temperature and, therefore, also the substrate.

At step 340, the process gas may be controlled such as starting the flow, stopping the flow, increasing or decreasing the rate of process gas flow, and/or changing the mix of gas compositions of the process gas. This may be accomplished by a controller such as controller 205.

At step 345 the microwave source such as, e.g., microwave source 120 may be controlled. The control may include start and stopping of a microwave field, intensity of the microwave field, targeting of the microwave field, repositioning of the microwave field in relation to the substrate. Control of the microwave field, and hence the plasma, may control the thickness of the carbon film deposited on the substrate and/or the rate of deposition. The process may end at step 350.

Process duration for depositing the carbon film such as the process of FIG. 3 can be several minutes to several hours.

The resulting matrix produced may comprise a substrate having an applied carbon film. The matrix may be substantially transparent. The applied carbon film may be a diamond film. The applied carbon film may comprise a diamond film that is formed with and/or at the surface of the substrate. The matrix may be substantially transparent.

While the disclosure has been described in terms of exemplary embodiments, those skilled in the art will recognize that the disclosure can be practiced with modifications in the spirit and scope of the appended claims. These examples are merely illustrative and are not meant to be an exhaustive list of all possible designs, embodiments, applications or modifications of the disclosure.

What is claimed:

1. A system for forming a film on a substrate, the system comprising:
a source of gas that provides at least a carbon-based gas;
a holding device to hold a target substrate;
an environment configured to contain the gas about the target substrate; and
a microwave source configured to project a microwave field towards the target substrate to create a carbon film upon the target substrate for creating a stronger and more scratch resistant substrate with enhanced thermal transport properties.

2. The system of claim 1, wherein the gas comprises a hydrogen-based gas.

3. The system of claim 1, wherein the gas comprises a hydrocarbon gas.

4. The system of claim 3, wherein the gas comprises methane.

5. The system of claim 1, wherein the gas further comprises an inert gas.

6. The system of claim 5, wherein the gas further comprises at least one of oxygen and nitrogen.

7. The system of claim 1, wherein the carbon film comprises a diamond film.

8. The system of claim 1, wherein the target substrate comprises one of: glass, borosilicate glass, aluminosilcate glass, yttria-stabiltzed zirconia, quartz, transparent aluminum-oxide, and a transparent plastic.

9. The system of claim 1, wherein the target substrate comprises ion-exchange glass.

10. The system of claim 1, wherein the holding device is configured to move in one or more dimensions.

11. The system of claim 1, wherein the holding device is itself configured to be cooled or heated.

12. The system of claim 1, wherein the environment comprises a chamber configured to create a partial pressure of gas and the microwave source is configured to excite the gas to create plasma within the chamber to deposit the carbon film on the target substrate.

13. The system of claim 1, further comprising a computer controller that is configured to control at least one of: targeting of the microwave source, positioning of the holding device relative to the microwave source, flow of the gas, temperature of the holding device, start and stop times of the microwave field, intensity of the microwave field, orientation of the substrate, pressure of the environment, and a thickness of the carbon film.

14. The system of claim 1, wherein the thickness of the created carbon film about 1 nm to about 10 μm.

15. The system of claim 1, wherein the target substrate with carbon film comprises a window usable in at least one of: a mobile phone, a tablet computer, a watch crystal, a laptop computer, and a consumer device.

16. A process to create a carbon film on a substrate, the process comprising the steps of:
providing a gas that includes a hydrocarbon gas; and
directing a microwave field towards a substrate, wherein the substrate is in contact with the hydrocarbon gas, the microwave field creating plasma to produce a layer of carbon film on the substrate thereby producing a stronger and more scratch resistant substrate.

17. The process of claim 16, wherein the carbon film is a diamond film.

18. The process of claim 16, wherein the providing step provides an environment of the gas, wherein the substrate is in the gas environment.

19. The process of claim 16, further comprising the step of providing a holding device to hold the substrate, wherein the holding device is temperature controlled and adjustable in orientation.

20. The process of claim 16, wherein the wherein the substrate comprises one of:
glass, borosilicate glass, aluminosilcate glass, yttria-stabiltzed zirconia, quartz, transparent aluminum-oxide and a transparent plastic.

21. The process of claim 16, wherein the substrate comprises ion-exchange glass.

22. The process of claim 16, further comprising providing a computer controller that is configured to control at least one of: targeting of the microwave source, positioning of the holding device relative to the microwave source, flow of the gas, temperature of the holding device, start and stop times of the microwave filed, intensity of the microwave field, orientation of the substrate, pressure of the environment, and a thickness of the carbon film.

23. The process of claim 16, wherein the directing step creates a carbon film having a thickness of about 1 nm to about 10 μm.

24. The process of claim 16, wherein the directing step creates a window usable in at least one of: a mobile phone, a tablet computer, a watch crystal, a laptop computer, and a consumer device.
